(19) United States
(12) Patent Application Publication
(10) Pub. No.: US 2011/0277834 A1
(43) Pub. Date: Nov. 17, 2011

(54) POLYMER SHEET FOR SOLAR CELL BACKSHEET AND SOLAR CELL MODULE

(75) Inventors: Akira HATAKEYAMA, Kanagawa (JP); Shinji TANAKA, Kanagawa (JP); Toshihiro ODA, Kanagawa (JP)

(73) Assignee: FUJIFILM CORPORATION, Tokyo (JP)

(21) Appl. No.: 13/108,593

(22) Filed: May 16, 2011

(30) Foreign Application Priority Data
May 17, 2010 (JP) 2010-113599
May 11, 2011 (JP) 2011-106461

(51) Int. Cl. H01L 31/0216

(52) U.S. Cl. 136/256

(57) ABSTRACT

The present invention provides a polymer sheet for a solar cell backsheet, which has high light reflectance, and adequate adhesion and adhesion durability, and which includes at least a support and polymer layers on both surfaces of the support, the polymer layers including white inorganic fine particles and a binder, a content of the white inorganic fine particles being in a range of from 4 g/m² to 12 g/m² per one polymer layer, and a content ratio (white inorganic fine particles/binder) of the white inorganic fine particles to the binder being in a range of from 1.5 to 8.0 by mass per one polymer layer.

### CROSS-REFERENCE TO RELATED APPLICATION

This application claims priority under 35 USC 119 from Japanese Patent Application Nos. 2010-113599, filed on May 17, 2010, and 2011-106461, filed on May 11, 2011, the disclosures of which are incorporated by reference herein.

### BACKGROUND OF THE INVENTION

1. Technical Field

The present invention relates to a polymer sheet for a backsheet for a solar cell, the polymer sheet being placed on an opposite side from a sunlight incident side of a solar cell element, and to a solar cell module provided with the polymer sheet.

2. Background Art

Solar cells are electricity generating systems that discharge no carbon dioxide upon electric power generation and place a small burden on the environment. Solar cells have been spreading rapidly in recent years.

A solar cell module generally has a structure in which solar cells are sandwiched between a front face glass on a sunlight incident side and a so-called backsheet that is placed on the opposite side (rear side) from the sunlight incident side. A space between the front face glass and the solar cells and a space between the solar cells and the backsheet are respectively sealed with an EVA (ethylene-vinylacetate) resin or the like.

The backsheet serves to prevent moisture penetration from the rear face of the solar cell module. Conventionally, glass, fluoro resin or the like was used for the backsheet, but in recent years, in consideration of cost, polyester has started to be used. The backsheet is not merely a polymer sheet, but depending on the circumstances, is provided with various functions as described below.

For example, a backsheet, which has white inorganic fine particles, such as titanium oxide, added therein so as to be provided with a function of light reflection as one of the above functions, is demanded in some cases. This is for the purpose of increasing efficiency of electric power generation by means of returning back to the cells, by diffuse reflection sunlight that has entered from the front face of the module and passed through the cells. Regarding this point, an example of a white polyethylene terephthalate film that includes white inorganic fine particles added therein has been disclosed (see, Japanese Patent Application Laid-Open (JP-A) Nos. 2003-060218 and 2006-210557, for example). In addition, an example of a rear face protecting sheet having a white ink layer that includes a white pigment therein has been also disclosed (see, JP-A No. 2006-210557, for example).

Furthermore, there are occasions where an readily-adhesive layer is provided on the outermost layer of a back sheet in order to obtain strong adhesion between the back sheet and an EVA sealing material. In this regard, there is disclosed a technique of providing a thermally adhesive layer on a white polyethylene terephthalate film (see, for example, JP-A No. 2003-060218).

### SUMMARY OF THE INVENTION

According to an aspect of the invention, a polymer sheet for a solar cell backsheet, which has high light reflectance, and adequate adhesion and adhesion durability, and which includes at least a support and polymer layers on both surfaces of the support, the polymer layers including white inorganic fine particles and a binder, a content of the white inorganic fine particles being in a range of from 4 g/m² to 12 g/m² per one polymer layer, and a content ratio (white inorganic fine particles/binder) of the white inorganic fine particles to the binder being in a range of from 1.5 to 8.0 by mass per one polymer layer, and a solar cell module including the polymer sheet for a solar cell backsheet, are provided.

### Problems to be Addressed by the Invention

For the backsheet, still further improvement of the light reflection performance is demanded from the viewpoint of power generation efficiency and the like. The backsheet generally has a structure of being bonded to a sealant (for instance, an EVA-based sealant). In this case, adhesion and adhesion durability over time between the backsheet and sealant is extremely important. In addition, adhesion and adhesion durability between a support and each layer that form the backsheet is also essential.

However, a backsheet that satisfies all of the requirements of adequate light reflection performance, adhesion and adhesion durability has not been attained at present.

The present invention has been accomplished in view of the above circumstances. It is an object of the present invention to provide a polymer sheet for a solar cell backsheet that exhibits high light reflectance, and adequate adhesion and adhesion durability.

Further, it is another object of the present invention to provide a solar cell module that is low in cost and exhibits stable power generation efficiency.

### Solution to Problem

Exemplary embodiments according to the aspect of the invention include, but are not limited to the following items <1> to <15>.

<1> A polymer sheet for a solar cell backsheet, the polymer sheet including a support, and a polymer layer on each surface of the support, each polymer layer including white inorganic fine particles and a binder, a content of the white inorganic fine particles being in a range of from 4 g/m² to 12 g/m² per one polymer layer, and a content ratio (white inorganic fine particles/binder) of the white inorganic fine particles to the binder being in a range of from 1.5 to 8.0 by mass per one polymer layer.
<2> The polymer sheet for a solar cell backsheet according to the item <1>, wherein the binder is at least one polymer selected from the group consisting of a polyolefin resin, an acrylic resin and a silicone resin.
<3> The polymer sheet for a solar cell backsheet according to the item <1> or the item <2>, wherein one of the polymer layer includes a silicone resin as the binder, and the other of the polymer layers includes a polyolefin resin or an acrylic resin as the binder.
<4> The polymer sheet for a solar cell backsheet according to the item <3>, further including a protective polymer layer which includes a resin selected from the group consisting of a silicone resin and a fluorocarbon resin, and inorganic fine particles in an amount of 1% by mass with respect to a total mass of the protective polymer layer, on the one of the polymer layers including the silicone resin as the binder.
<5> The polymer sheet for a solar cell backsheet according to any one of the items <1> to <4>, wherein the polymer layer further comprises a crosslinking agent in a range of from 0.5% by mass to 25% by mass with respect to a total mass of the binder contained in the polymer layers.
<6> The polymer sheet for a solar cell backsheet according to any one of the items <1> to <5>, wherein the support includes polyester.
<7> The polymer sheet for a solar cell backsheet according to the item <6>, wherein the polyester is a straight chain saturated polyester that is synthesized from an aromatic dibasic acid or an ester-forming derivative thereof, and a diol or an ester-forming derivative thereof.
<8> The polymer sheet for a solar cell backsheet according to the item <6> or the item <7>, wherein the polyester is synthesized by solid phase polymerization by which a polymerization degree of the polyester is increased, after primary polymerization, by heating the polyester at a temperature in a range of from about 170° C. to about 240° C. for a period of about 5 to about 100 hours in a vacuum or in an atmosphere of nitrogen gas.
<9> The polymer sheet for a solar cell backsheet according to any one of the items <6> to <8>, wherein a content of carboxyl groups in the polyester is 55 moles per ton or less.
<10> The polymer sheet for a solar cell backsheet according to any one of the items <1> to <9>, wherein a thickness of the support is in a range of 25 μm to 300 μm.
<11> The polymer sheet for a solar cell backsheet according to any one of the items <1> to <10>, wherein the white inorganic fine particles include at least one selected from the group consisting of titanium dioxide, barium sulfate, silicon oxide, aluminum oxide, magnesium oxide, calcium carbonate, kaolin, and talc.
<12>. The polymer sheet for a solar cell backsheet according to any one of the items <1> to <11>, wherein a volume average particle diameter of the white inorganic fine particles is in a range of from 0.15 μm to 0.50 μm.
<13> The polymer sheet for a solar cell backsheet according to the item <4>, wherein the crosslinking agent is a carbodiimide-based crosslinking agent or an oxazoline-based crosslinking agent.
<14> The polymer sheet for a solar cell backsheet according to any one of the items <1> to <13>, further including a rear face protecting layer disposed on an opposite side of the support from a surface of the support that faces a cell side board.
<15> The polymer sheet for a solar cell backsheet according to the item <14>, wherein the rear face protecting layer includes a fluorocarbon-based polymer or a silicone-based polymer, as a main binder.
<16> The polymer sheet for a solar cell backsheet according to any one of the items <1> to <15>, wherein an elongation at break after storage for 50 hours under a condition of 120° C. and 100% RH, is 50% or more with respect to an elongation at break before the storage.
<17> A solar cell module comprising the polymer sheet for a solar cell backsheet according to any one of the items <1> to <16>.

### BRIEF DESCRIPTION OF THE DRAWINGS

Exemplary embodiments of the invention will be described in detail based on the following figures, wherein:

FIG. 1 is a schematic cross-sectional diagram illustrating a configurative example of a solar cell module according to the present invention.

### DETAILED DESCRIPTION OF THE INVENTION

Hereinafter, the polymer sheet for a solar cell backsheet according to the present invention, and the solar cell module with the solar cell backsheet are described in detail.

Polymer Sheet for Solar Cell Backsheet

The polymer sheet (hereinafter, also referred to as “polymer sheet of the present invention” arbitrarily) for a solar cell backsheet according to the present invention includes therein, at least a support and polymer layers on both surfaces of the support, the polymer layers including as ingredients thereof white inorganic fine particles and a binder. The content of the white inorganic fine particles is in a range of from 4 g/m² to 12 g/m² per one polymer layer. The content ratio (white inorganic fine particles/binder) of the white inorganic fine particles to the binder is in a range of from 1.5 to 8.0 by mass per one polymer layer.

Note that, in the following description, the polymer layers of the polymer sheet of the present invention that have the above specific configuration are referred to as “specific polymer layers” arbitrarily.

The polymer sheet of the present invention include as constituents thereof, at least a support and specific polymer layers on both surface side of the support. The polymer sheet may serve as a solar cell backsheet (hereinafter, also referred to as simply “backsheet”).

The polymer sheet of the present invention may be the one that has only the support and specific polymer layers or the one that has an optional (other) layer other than the specific polymer layers on one side or both surfaces side of the support. The other layer may be a single layer or two or more layers.

When the polymer sheet of the present invention includes therein the other layer other than the specific polymer layers, the other layer is laminated onto a face to be laminated of the support before or after the specific layers are formed thereon.

The details of the specific polymer layers and the other layer other than the specific polymer layers are described later.

The polymer sheet of the present invention includes therein, on both surface sides of the support, the polymer layers that contain white inorganic fine particles and a binder in specific amounts, whereby the polymer sheet exhibits high light reflectance and has excellent adhesion to a solar cell main body (solar cells). In addition, even when the polymer sheet of the present invention is left in a wet and hot environment over time, failures such as delamination of the polymer sheet from the solar cell main body are effectively prevented. Therefore, a solar cell module that possesses the polymer sheet of the present invention as a backsheet thereof is capable of keeping stably power generation performance over a long period of time.

Support

As a material that composes the support, a polyolefin such as a polyester, a polypropylene or a polyethylene, a fluorocarbon polymer such as polyvinyl fluoride, or the like may be used. Among these, a polyester is preferable.

As the polyester that is used for the support, a straight chain saturated polyester is preferable, which is synthesized form an aromatic dibasic acid or an ester-forming derivative thereof and a diol or an ester-forming derivative thereof. The polyester may be a homo-polymer or a copolymer. The polyester may be blended with a small amount of the other kind of resins, for instance, polyimide or the like.

Specific examples of the polyester include: polyethylene terephthalate; polyethylene isophthalate; polybutylene terephthalate; poly(1,4-cyclohexylene dimethylene terephthalate); and polyethylene-2,6-naphthalate.

Among these, as the polyester, polyethylene terephthalate is particularly preferable in consideration of balancing between mechanical properties and cost.

The content of carboxyl groups in the polyester that is used for the support is preferably 55 moles/t or less and more preferably 35 moles/t or less. When the content of carboxyl groups is 55 moles/t or less, hydrolysis resistance of the support may be kept and degradation in strength after the support is left in a wet and hot environment over time may be suppressed small. The lower limit of the content of carboxyl groups is 2 moles/t desirably, from the viewpoint of keeping adequately adhesion to a layer that is formed on the support.

The content of carboxyl groups in the polyester may be adjusted by selecting the kind of polymerization catalysts, film forming conditions (including film forming temperature or time), and solid-phase polymerization.

In order to polymerize the polyester according to the invention, from the viewpoint of suppressing the content of carboxyl groups to a predetermined range or less, it is preferable to use an Sb-based compound, a Ge-based compound or a Ti-based compound as a catalyst, and among them, a Ti-based compound is particularly preferable.

In the case of using a Ti-based compound, an embodiment of performing polymerization by using the Ti-based compound as a catalyst at a proportion in the range of from 1 ppm to 30 ppm, and more preferably from 3 ppm to 15 ppm, in terms of the Ti element, is preferable. When the proportion of the Ti-based compound is in the range described above, the content of terminal carboxyl groups can be adjusted to the range shown below, and the resistance to hydrolysis of the support can be maintained at a low level.

Polyester synthesis using the titanium-based compound may be performed by applying a method described in Japanese published examined application patent No. 8-301,198, Japanese patent Nos. 2,543,624, 3,335,683, 3,717,380, 3,897,756, 3,962,226, 3,979,866, 3,996,871, 4,000,867, 4,053,837, 4,127,119, 4,134,710, 4,159,154, 4,269,704, 4,313,538, and the like.

The polyester of the present invention is preferably subjected to solid phase polymerization after polymerization. By means of the solid phase polymerization, a preferable content of carboxyl groups may be attained. Solid phase polymerization is a method for increasing a polymerization degree of polyester, after primary polymerization, by heating the polyester at a temperature in a range of from about 170° C. to about 240° C. for a period of about 5 hours to about 100 hours in a vacuum or in an atmosphere of nitrogen gas. Specifically, a synthetic method described in Japanese patent Nos. 2,621,563, 3,121,876, 3,136,774, 3,603,585, 3,616,522, 3,617,340, 3,680,523, 3,717,392, 4,167,159, and the like, is applicable to the solid phase polymerization of polyester. The polyester used for the support in exemplary embodiment of the invention is preferably biaxially stretched from the viewpoint of mechanical strength.

The thickness of the support is preferably from 25 μm to 300 μm. When the thickness of the support is 25 μm or more, adequate mechanical strength may be attained. In the case of the thickness of the support being 300 μm or less, advantageous cost may be attained.

Specific Polymer Layers

The specific polymer layers of the polymer sheet according to the present invention are disposed on both faces of the support directly to the surface thereof or through the other layers, and include as ingredients thereof at least white inorganic particles and a binder.

The specific polymer layers are capable of serving as a reflection layer.

The specific polymer layers are preferably formed in a manner that they are in contact with the surface of the support.

The content of the white inorganic fine particles (A) in the specific polymer layers is in a range of from 4 g/m² to 12 g/m² per one specific polymer layer; and the content ratio (A/B) of the white inorganic fine articles (A) to the binder (B) is in a range of preferably from 1.5 to 8.0 by mass per one specific polymer layer.

In the polymer sheet of the present invention, the specific polymer layers, which contain the white inorganic fine particles in a specific amount and have a content ratio of the white inorganic fine particles to the binder in a specific range, are disposed on both faces of the support. Whereby, in a solar cell module that possesses the polymer sheet as a backsheet thereof, part of incident light that passes through solar cells and reaches the backsheet without being used for power generation may be reflected back to the solar cells with a high efficiency. Therefore, the power generation efficiency of the solar cell module that possesses the backsheet may be increased as compared with conventional solar cell modules. In addition to that, the specific polymer layers have such configuration as described above, so that they have a high adhesion to an adjacent layer thereof (for instance, an EVA-based sealant layer, a readily-adhesive layer, or the like). Delamination of the backsheet from the solar cell main body, which is caused by degradation of adhesion between the specific polymer layers and the adjacent layers thereof, hardly occurs while a high light reflectance is preserved. The reason why the adhesion is improved as described above is not clear, but an anchor effect may be considered to work at the interface between the specific polymer layers and the adjacent layers thereof. Further, the specific polymer layers exhibit a high durability against operation under wet and heat condition or the like, so that degradation of adhesion is small even when they are subjected to a long time operation.

Furthermore, the specific polymer layers may be formed with an adequate face condition even when they are formed by coating, because the content ratio of the white inorganic fine particles to the binder is regulated in a specific range.

White Inorganic Fine Particles

The specific polymer layers include therein at least one kind of white inorganic fine particles.

As the white inorganic fine particles, for instance, an inorganic pigment such as titanium dioxide, barium sulfate, silicon oxide, aluminum oxide, magnesium oxide, calcium carbonate, kaolin, or talc may be selected appropriately and included. Among these, titanium dioxide is preferable.

The content of the white inorganic fine particles in the specific polymer layers is required to be in a range of from 4 g/m² to 12 g/m² per layer, more preferably from 5 g/m² to 11.5 g/m², and even more preferably from 5.5 g/m² to 11 g/m².

When the content of the white inorganic fine particles in the specific polymer layers is less than 4 g/m², the light reflectance becomes insufficient. On the other hand, when the content exceeds 12 g/m², the face condition, adhesion and adhesion durability to adjacent layers of the specific polymer layers become insufficient.

In the specific polymer layers, the content ratio (white inorganic fine particles/binder) of the white inorganic fine particles to the binder is required to be in a range of from 1.5 to 8.0 and more preferably from 2.0 to 6.0.

When the ratio of the white inorganic fine particles to the binder in the specific polymer layers is less than 1.5, the light reflectance becomes insufficient. On the other hand, when the ratio exceeds 8.0, the face condition, adhesion, and adhesion durability to adjacent layers of the specific polymer layers become insufficient.

The average particle size of the white inorganic fine particles is in a range of preferably from 0.03 μm to 0.8 μm, in terms of volume average particle size, and more preferably from 0.15 μm to 0.5 μm. When the average particle size is in this range, the backsheet is provided with a higher light reflectance.

Here, the average particle size is represented by a value that is measured with a “LA-950 High Performance Laser Diffraction Analyzer”; trade name, manufactured by HORIBA, Ltd.

Binder

The specific polymer layers include therein at least one binder.

Examples of a preferred binder that is included in the specific polymer layers include: polyolefin resin; acrylic resin; and silicone rein.

The polyolefin resin contains as a main ingredient thereof a polyolefin such as a polyethylene or a polypropylene. Further, the polyolefin resin may be a copolymer which includes an ingredient of polyolefin and an ingredient of the other polymer. Examples of the other polymer as the copolymer ingredient include: polyvinylacetate; polyvinyl alcohol; polyvinyl chloride; polyacrylic acid; polymethacrylic acid and the like. Besides these, a so-called ionomer that is obtained by copolymerizing acrylic acid or methacrylic acid is also preferable. Examples of the polyolefin resin include “CHEMIPEARL S-120” and “CHEMIPEARL S-75N” (trade names: both are manufactured by Mitsui Chemicals, Inc.).

The acrylic resin represents a polymer which is obtained by polymerizing an acryl monomer such as methyl methacrylate, ethyl methacrylate, methyl acrylate or the like. Further, the acrylic resin may be a polymer obtained by copolymerizing acrylic acid or methacrylic acid, when needed. Examples of the acrylic resin include “JURYMER ET410”, “JURYMER SEK301”, and “JURYMER FC30” (trade names: all of them are manufactured by Nippon Junyaku K.K.).

The silicone resin represents a polymer that has a siloxane bond in the main or side chain thereof. As the silicone resin, a composite polymer that contains a polymer having the siloxane bond and the other polymer (for instance, an acryl polymer) as a copolymer ingredient, is preferable. The composite polymer according to the invention may be a block copolymer in which a polysiloxane and at least one polymer are copolymerized. The polysiloxane and the polymer that is copolymerized may be respectively composed of a single compound, or may be composed of two or more kinds.

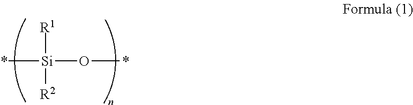

In Formula (1), R¹ and R² each independently represent a hydrogen atom, a halogen atom, a hydroxyl group, or a monovalent organic group. Herein, R¹ and R² may be identical with or different from each other. Plural R¹s may be identical with or different from each other, and plural R²s may be identical with or different from each other. n represents an integer of 1 or more.

In the “—(Si(R¹)(R²)—O)ₙ—” moiety ((poly)siloxane structural unit represented by Formula (1) above), which is a polysiloxane segment in the composite polymer, R¹ and R² may be identical with or different from each other, and respectively represent a hydrogen atom, a halogen atom, a hydroxyl group, or a monovalent organic group capable of covalent bonding with a Si atom.

The moiety “—(Si(R¹)(R²)—O)ₙ—” is a polysiloxane segment derived from various polysiloxanes having a straight chain, branched or cyclic structure.

Examples of the halogen atom represented by R¹ and R² include a fluorine atom, a chlorine atom, and an iodine atom.

The “monovalent organic group capable of covalent bonding with a Si atom,” which is represented by R¹ and R², may be unsubstituted or may be substituted. Examples of the monovalent organic group include an alkyl group (for example, a methyl group or an ethyl group), an aryl group (for example, a phenyl group), an aralkyl group (for example, a benzyl group or a phenylethyl group), an alkoxy group (for example, a methoxy group, an ethoxy group, or a propoxy group), an aryloxy group (for example, a phenoxy group), a mercapto group, an amino group (for example, an amino group or a diethylamino group), and an amido group.

Among them, from the viewpoints of adhesiveness to an adjacent material such as a polymer base material, and durability in a hot and humid environment, R¹ and R² are each independently preferably a hydrogen atom, a chlorine atom, a bromine atom, an unsubstituted or substituted alkyl group having 1 carbon atom to 4 carbon atoms (particularly, a methyl group or an ethyl group), an unsubstituted or substituted phenyl group, an unsubstituted or substituted alkoxy group, a mercapto group, an unsubstituted amino group, or an amido group, and more preferably an unsubstituted or substituted alkoxy group (preferably, an alkoxy group having 1 to 4 carbon atoms), from the viewpoint of durability in a hot and humid environment.

n is preferably 1 to 5,000, and more preferably 1 to 1,000.

The proportion of the —(Si(R¹)(R²)—O)ₙ— moiety (polysiloxane moiety represented by Formula (1)) in the composite polymer is preferably 15% by mass to 85% by mass relative to the total mass of the composite polymer, and inter alia, from the viewpoints of adhesiveness to the polymer base material and durability in a hot and humid environment, the proportion is more preferably in the range of 20% by mass to 80% by mass.

If the proportion of the polysiloxane moiety is 15% by mass or greater, the adhesiveness to the polymer base material and the adhesion durability upon exposure to a hot and humid environment are excellent. If the proportion is 85% by mass or less, when the composite polymer is used in a water dispersion, the stable dispersion effectively maintained.

There are no particular limitations on the polymer structural moiety that is copolymerized with the polysiloxane moiety as far as the polymer structural moiety contains no polysiloxane moiety, and the polymer structural moiety may be any polymer segment derived from any arbitrary polymer. Examples of a polymer that serves as a precursor of the polymer segment (precursor polymer) include various polymers such as a vinyl-based polymer (for example, an acrylic polymer), a polyester-based polymer, and a polyurethane-based polymer. From the viewpoints that preparation is easy and resistance to hydrolysis is excellent, a vinyl-based polymer and a polyurethane-based polymer are preferable, a vinyl-based polymer is more preferable, and an acrylic polymer is particularly preferable.

Representative examples of the vinyl-based polymer include various polymers such as an acrylic polymer, a carboxylic acid-vinyl ester-based polymer, an aromatic vinyl-based polymer and a fluoro-olefin-based polymer. Among them, from the viewpoints of the degree of freedom in design, an acrylic polymer (that is, an acrylic polymer structural moiety as the non-polysiloxane structural moiety) is particularly preferable.

In addition, the polymers that constitute the polymer structural moiety may be used alone, or two or more kinds may be used in combination.

Furthermore, the precursor polymer that constitutes the polymer structural moiety preferably contains at least one of an acid group and a neutralized acid group, and/or a hydrolyzable silyl group. Among such precursor polymers, a vinyl-based polymer can be prepared by using various methods such as, for example, (a) a method of copolymerizing a vinyl-based monomer containing an acid group, and a vinyl-based monomer containing a hydrolyzable silyl group and/or a silanol group, with a monomer capable of being copolymerized with these monomers; (2) a method of allowing a vinyl-based polymer containing a hydroxyl group and a hydrolyzable silyl group and/or a silanol group, which has been prepared in advance, to react with a polycarboxylic acid anhydride; and (3) a method of allowing a vinyl-based polymer containing an acid anhydride group and a hydrolyzable silyl group and/or a silanol group, which has been prepared in advance, to react with a compound having active hydrogen (water, alcohol, amine or the like).

Such a precursor polymer can be produced and obtained by using the method described in, for example, paragraphs [0021] to [0078] of JP-A No. 2009-52011.

The synthetic method of the composite polymer of the exemplary embodiment of the invention is described in, for example, the document of JP-A No. 11-209693.

The polymer layer according to the invention may use the composite polymer alone as a binder, or may use the composite polymer in combination with another polymer. When another polymer is used in combination, the proportion of the composite polymer according to the invention is preferably 30% by mass or greater, and more preferably 60% by mass or greater, based on the total amount of binders. When the proportion of the composite polymer is 30% by mass or greater, the polymer layer is excellent in the adhesiveness to the polymer base material and the durability in a hot and humid environment.

A weight average molecular weight of the composite polymer is preferably in a range of 5,000 to 100,000, and more preferably in a range of 10,000 to 50,000.

For the preparation of the composite polymer, methods such as (i) a method of allowing a precursor polymer to react with the polysiloxane having a structure of “—(Si(R¹)(R²)—O)ₙ—”, and (ii) a method of subjecting a silane compound having the structure of “—(Si(R¹)(R²)—O)ₙ—” in which R¹ and/or R² is a hydrolyzable group, to hydrolysis and condensation in the presence of a precursor polymer, can be used.

Examples of the silane compound used in the method (ii) include various silane compounds, but an alkoxysilane compound is particularly preferable.

In the case of preparing a composite polymer by the method (i), the composite polymer can be prepared by, for example, allowing a mixture of a precursor polymer and a polysiloxane to react, while optionally adding water and a catalyst, at a temperature of about 20° C. to 150° C. for about 30 minutes to 30 hours (preferably, at 50° C. to 130° C. for 1 hour to 20 hours). As the catalyst, various silanol condensation catalysts such as an acidic compound, a basic compound, and a metal-containing compound, can be added.

Furthermore, in the case of preparing a composite polymer by the method (ii), the composite polymer can be prepared by, for example, adding water and a silanol condensation catalyst to a mixture of a precursor polymer and an alkoxysilane compound, and subjecting the mixture to hydrolysis and condensation at a temperature of about 20° C. to 150° C. for about 30 minutes to 30 hours (preferably, at 50° C. to 130° C. for 1 to 20 hours).

Examples of the silicone resin include: “CERANATE WSA1060” (a content of polysiloxane structural moiety; about 75%) and “CERANATE WSA1070” (a content of polysiloxane structural moiety; about 30%) (trade names: both are manufactured by DIC Corp.); and “H7620”, “H7630”, and “H7650” (trade names: all of them are manufactured by Asahi Kasei Chemicals Corp.).

<Crosslinking Agent>

The specific polymer layer may contain at least one crosslinking agent, as necessary.

Preferable examples of a crosslinking agent include epoxy-based, isocyanate-based, melamine-based, carbodiimide-based and oxazoline-based crosslinking agents. Among them, a carbodiimide-based or an oxazoline-based crosslinking agent is preferable.

Example of the carbodiimide-based crosslinking agent includes CARBODILITE V-02-L2 (trade name, manufactured by Nisshinbo Industries, Inc.) and the like.

Specific examples of the oxazoline-based crosslinking agent include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethylene-bis-(2-oxazoline), 2,2′-octamethylene-bis-(2-oxazoline), 2,2′-ethylene-bis-(4,4′-dimethyl-2-oxazoline), 2,2′-p-phenylene-bis-(2-oxazoline), 2,2′-m-phenylene-bis-(2-oxazoline), 2,2′-m-phenylene-bis-(4,4′-dimethyl-2-oxazoline), bis-(2-oxazolinylcyclohexane) sulfide, and bis-(2-oxazolinylnorbornane) sulfide. Furthermore, (co)polymers of these compounds are also used with preference.

As the oxazoline-based crosslinking agent, EPOCROS K2010E, EPOCROS K2020E, EPOCROS K2030E, EPOCROS WS-500, EPOCROS WS-700 (trade names, all manufactured by Nippon Shokubai co., Ltd.) and the like can also be used.

The content of the crosslinking agent in the specific polymer layers is, with respect to the total mass of the binder contained in the specific polymer layers, in a range of preferably from 0.5% by mass to 25% by mass and more preferably from 1% by mass to 25% by mass. When the content of the crosslinking agent is in this range, the face condition and adhesion to adjacent layers of the specific polymer layers may be still more improved.

Surfactant

To the specific polymer layers, a surfactant may be added, when needed.

As a preferred surfactant, known surfactants such as anionic or nonionic may be used. The amount of the surfactant added is preferably from 0.1 mg/m² to 15 mg/m² and more preferably from 0.5 mg/m² to 5 mg/m². When the addition amount of the surfactant is 0.1 mg/m² or more, repelling of a coating liquid for the specific polymer layers is effectively prevented and the specific polymer layers may be formed adequately. When the addition amount is 15 mg/m² or less, adhesiveness of the specific polymer layer to other substances or the support may be performed adequately.

In the invention, an embodiment in which one layer of the specific polymer layers disposed on both surfaces of the support includes the silicone resin as a binder, and another layer of the specific polymer layers contains the olefin resin or the acrylic resin as a binder, is more preferable. In the embodiment, disposing a side having the another layer of the specific polymer layers so as to face to a cell side board of the solar cell and disposing the specific polymer layer containing the silicone resin to be an outermost layer or a neighbor layer to the outermost layer when the solar cell is constituted, properties in terms of excellent adhesiveness, adhesive durability and resistance to climate of the polymer sheet for a solar cell backsheet, may be enhanced.

Method of Forming Specific Polymer Layers

The specific polymer layers are formed by using a method of laminating a polymer sheet that contains the white inorganic fine particles and the binder to a support; a method of co-extruding specific polymer layers at the time when a support is formed; a method of forming the specific polymer layers by coating a coating liquid that contains the white inorganic fine particles and the binder; or other methods.

The specific polymer layers are preferably formed in a manner that they contact the surface of the support directly.

Among the above methods, a method of forming the specific layers by coating is preferable, from the viewpoints that the method is simple and provides a uniform thin layer.

In the case of forming the specific polymer layer by coating, known coating methods using, for example, a gravure coater or a bar coater can be used.

The coating liquid may be an aqueous system using water as a coating solvent, or a solvent-based system using an organic solvent such as toluene, methyl ethyl ketone or the like. Among them, from the viewpoint of environmental load, it is preferable to use water as the solvent. The coating solvent may be used singularly, or in a combination of two or more kinds thereof.

The solvent used for the coating liquid may be water or an organic solvent such as toluene or methylethyl ketone. The solvent may be used each kind singly or as a mixture of two or more kinds thereof.

In a particularly preferable method, a waterborne coating liquid in which the white inorganic fine particles and the binder are dispersed in water is prepared and coated. In this case, the ratio of water in the solvent is preferable 60% by mass or more and more preferably 80% by mass or more.

The specific polymer layers may be coated on both faces of the support at the same time or one face by one face.

The specific polymer layers formed on both faces of the support may have the same or different composition from each other.

The thickness of the specific polymer layers is preferably from 1.5 μm to 12 μm per layer and more preferably from 2.0 μm to 8.0 μm. When the thickness of the specific polymer layers is in the range of from 1.5 μm to 12 μm, the light reflectance and face condition may be maintained higher and more adequately.

Other Layers

The polymer sheet of the present invention may include therein, when needed, other than the specific polymer layers, the other layers such as a readily-adhesive layer that assures adhesion to a sealant, a back layer (or sheet) that protects the rear surface which is in an opposite side to the light incident side of the solar cell, or the like.

Readily-Adhesive Layer

The polymer sheet of the present invention may have a readily-adhesive layer on the specific polymer layers. The readily-adhesive layer serves to bond together firmly a back sheet of the polymer sheet and a sealant that seals solar cell elements (hereinafter, also referred to as “power generating elements”) that are disposed on a cell side board (solar cell main body).

The readily-adhesive layer may include as ingredients thereof a binder and inorganic fine particles. Further, the other ingredients such as an additive may be included therein, when needed. The readily-adhesive layer is preferably formulated in a manner that it provides an adhesion of 10 N/cm or more (preferably, 20 N/cm or more) to an ethylene-vinylacetate sealant (EVA: ethylene-vinylacetate copolymer) that serves to seal the power generating elements on the cell side board. When the adhesion is 10 N/cm or more, a wet and heat resistance that assures adhesion may be easily attained.

Note that, the adhesion is may be adjusted by using a method of regulating the amount of the binder and inorganic fine particles in the readily-adhesive layer, a method of applying a corona treatment to a face that is bonded to the sealant of the backsheet, or other methods.

<Binder>

The readily-adhesive layer may contain at least one binder.

Examples of the binder that is suitable for the readily-adhesive layer include a polyester, a polyurethane, an acrylic resin, and a polyolefin. Among them, an acrylic resin or a polyolefin is preferable from the viewpoint of durability. Furthermore, a composite resin of acrylic resin ingredient and silicone resin ingredient is also preferable as the acrylic resin.

Preferable examples of the binder include, as specific examples of the polyolefin, CHEMIPEARL S-120 and S-75N (trade names, all manufactured by Mitsui Chemicals, Inc.); as specific examples of the acrylic resin, JURYMER ET-410 and SEK-301 (trade names, all manufactured by Nihon Junyaku Co., Ltd.); and as specific examples of the composite resin of acrylic resin ingredient and silicone resin ingredient, CERANATE WSA1060 and WSA1070 (trade names, all manufactured by DIC Corp.), H7620, H7630 and H7650 (trade names, all manufactured by Asahi Kasei Chemicals Corp.).

The content of the binder in the readily-adhesive layer is preferably in the range of 0.05 g/m² to 5 g/m². Inter alia, the content is more preferably in the range of 0.08 g/m² to 3 g/m². If the content of the binder is 0.05 g/m² or more, a desired adhesive power is easily obtained, and if the content is 5 g/m² or less, a satisfactory surface state can be obtained.

<Fine Particles>

The readily-adhesive layer may contain at least one kind of inorganic fine particles. Examples of the inorganic fine particles include fine particles of silica, calcium carbonate, magnesium oxide, magnesium carbonate and tin oxide. Among them, the fine particles of tin oxide and silica are preferable from the viewpoint that the decrease in adhesiveness is small when the readily-adhesive layer is exposed to a hot and humid atmosphere.

The particle size of the inorganic fine particles is preferably about 10 nm to 700 nm, and more preferably about 20 nm to 300 nm, as the volume average particle size. When the particle size is in this range, more satisfactory adhesiveness can be obtained. The particle size is a value measured with a laser analysis/scattering type particle size distribution analyzer LA950 (trade name, manufactured by Horiba, Ltd.).

There are no particular limitations on the shape of the inorganic fine particles, and the inorganic fine particles having any of a spherical shape, an amorphous shape, a needle shape and the like can be used.

A content of the inorganic fine particles is in the range of 5% by mass to 400% by mass, based on the binder in the readily-adhesive layer. If the content of the inorganic fine particles is less than 5% by mass, satisfactory adhesiveness cannot be retained when the readily-adhesive layer is exposed to a hot and humid atmosphere, and if the content is greater than 400% by mass, the surface state of the readily-adhesive layer is deteriorated.

Inter alia, the content of the inorganic fine particles is preferably in the range of 50% by mass to 300% by mass.

<Crosslinking Agent>

The readily-adhesive layer can contain at least one crosslinking agent.

Examples of the crosslinking agent that is suitable for the readily-adhesive layer include epoxy-based, isocyanate-based, melamine-based, carbodiimide-based and oxazoline-based crosslinking agents. Among them, from the viewpoint of securing adhesiveness after a lapse of time under heat and moisture, an oxazoline-based crosslinking agent is particularly preferable.

As the specific examples of the oxazoline-based crosslinking agent, oxazoline-based crosslinking agents above described usable for the specific polymer layer are also preferably exemplified for readily-adhesive layer.

A content of the crosslinking agent in the readily-adhesive layer is preferably 5% by mass to 50% by mass based on the binder in the readily-adhesive layer, and inter alia, more preferably 20% by mass to 40% by mass. When the content of the crosslinking agent is 5% by mass or greater, a satisfactory crosslinking effect is obtained, and the strength of the readily-adhesive layer and adhesiveness of the readily-adhesive layer between the adjacent layer can be maintained. When the content is 50% by mass or less, a prolonged pot life of the coating liquid can be maintained.

<Additives>

The readily-adhesive layer according to the invention may optionally contain a known matting agent such as polystyrene, polymethyl methacrylate or silica; a known anionic or nonionic surfactant; and the like.

—Method of Forming Readily-Adhesive Layer—

The formation of the readily-adhesive layer may be carried out by using a method of pasting a polymer sheet having easy adhesiveness to a substrate, or a method based on coating. Among them, the method based on coating is preferable from the viewpoints that the method is convenient, and it is possible to form a uniform thin film.

In regard to the coating method, known coating methods using, for example, a gravure coater or a bar coater can be used.

The coating solvent used in the preparation of the coating liquid may be water, or may be an organic solvent such as toluene or methyl ethyl ketone. The coating solvent may be used singularly, or in a combination of two or more kinds thereof.

There are no particular limitations on the thickness of the readily-adhesive layer, but the thickness is usually preferably 0.05 μm to 8 μm, and more preferably in the range of 0.1 μm to 5 μm. When the thickness of the readily-adhesive layer is 0.05 μm or thicker, the necessary adhesiveness can be suitably obtained, and when the thickness is 8 μm or thinner, the surface state becomes more satisfactory.

Back Layer

The polymer sheet of the present invention may further have as a protective layer, other than the specific polymer layer, a back layer that protects the rear face which is in an opposite side to the light incident side of the solar cell, of the polymer sheet. The back layer is a rear face protecting layer that is disposed on the opposite side of a face facing to the cell side board of the support. The back layer may have a single layer structure or a structure of laminating two or more layers. The back layer is disposed preferably as an outermost layer remotest from the support.

In a preferred embodiment of the back layer, the main binder thereof is a fluorocarbon resin (fluorocarbon binder). In another preferred embodiment of the back layer, the main binder thereof is a silicone resin (silicone binder).

<Binder>

Specific examples of the fluorocarbon resin include: polytetrafluoro ethylene; polyvinyl fluoride; polyvinylidene fluoride; polychlorotrifluoro ethylene; polytetrafluoro propylene and the like.

These polymers may be a homo polymer that is obtained by polymerizing each monomer singly or a copolymer that is obtained by copolymerizing two or more kinds of monomers. Further, a copolymer that is obtained by copolymerizing these monomers with the other monomers may be included.

Examples of these polymers include: a copolymer of tetrafluoro ethylene and tetrafluoro propylene; a copolymer of tetrafluoro ethylene and vinylidene fluoride; a copolymer of tetrafluoro ethylene and ethylene; a copolymer of tetrafluoro ethylene and propylene; a copolymer of tetrafluoro ethylene and vinylether; a copolymer of tetrafluoro ethylene and perfluoro vinylether; a copolymer of chlorotrifluoro ethylene and vinylether; a copolymer of chlorotrifluoro ethylene and perfluoro vinylether; and the like. As the fluorocarbon resin, commercial products launched in the market may be used. Examples of the commercial products include OBBLIGATO SW0011F; trade name, manufactured by AGC COAT-TECH Co., Ltd. and the like.

Examples of the silicone resin include: a silicone polymer or a denatured silicone polymer; and a composite polymer of a silicone polymer and an acryl polymer. Specifically, the same silicone resin used in the specific polymer layer may be used as the silicone resin for the binder of the back layer. Examples of the silicone resin include: “CERANATE WSA1060” and “CERANATE WSA1070” (trade names: both are manufactured by DIC Corp.); and “H7620”, “H7630”, and “H7650” (trade names: all of them are manufactured by Asahi Kasei Chemicals Corp.).

The back layer may include therein a crosslinking agent, a surfactant, a filler, or the like, when needed.

In the invention, an embodiment in which one layer of the specific polymer layers disposed on both surfaces of the support includes the silicone resin as a binder, (in this case, another layer of the specific polymer layers preferably contains the olefin resin or the acrylic resin as a binder), and a back layer (a protective polymer layer) containing; a resin selected from the group consisting of a silicone resin and a fluorocarbon resin; and inorganic fine particles of a content of 1% by mass or less with respect to the total mass of the layer (preferably containing no inorganic fine particles) is further disposed on the specific polymer layer containing the silicone resin, is more preferable. Herein, the inorganic fine particles include white inorganic fine particles contained in the specific polymer layer and inorganic fine particles contained in the readily-adhesive layer.

Crosslinking Agent

As a crosslinking agent that may be included in the back layer, a crosslinking agent of epoxy, isocyanate, melamine, carbodiimide, oxazoline, and the like may be mentioned. Among these, a crosslinking agent of carbodiimide or oxazoline is preferable.

Examples of the crosslinking agent of carbodiimide include “CARBODILITE V-02-L2” (trade name: manufactured by Nisshinbo Industries, Inc.). Examples of the crosslinking agent of oxazoline include “EPOCROSS WS-700” and “EPOCROSS K-2020E” (trade names: both are manufactured by Nippon Shokubai Co., Ltd.).

An addition amount of the crosslinking agent is, with respect to the binder in the back layer, preferably from 0.5% by mass to 25% by mass and more preferably from 2% by mass to 20% by mass. When the addition amount of the crosslinking agent is 0.5% by mass or more, a sufficient crosslinking effect may be obtained while the strength and adhesion of the back layer are preserved adequately. In the case of 25% by mass or less, the pot life of the coating liquid may be maintained long.

Surfactant

As the surfactant, known surfactants including anionic or nonionic may be used. When the surfactant is added to the back layer, an addition amount thereof is preferably from 0.1 mg/m² to 15 mg/m² and more preferably from 0.5 mg/m² to 5 mg/m². When the addition amount of the surfactant is 0.1 mg/m² or more, repelling of a coating liquid for the back layer is effectively prevented and layer formation may be performed adequately. In the case of the surfactant being 15 mg/m² or less, layer bonding of the back layer may be performed rightly.

Filler

To the back layer, filler may be added further. As the filler, known filler such as colloidal silica, titanium dioxide or the like may be used. An addition amount of the filler is, with respect to the binder in the back layer, preferably 20% by mass or less and more preferably 15% by mass or less. When the addition amount of the filler is 20% by mass or less, face condition of the back layer may be maintained more adequately.

Thickness

The thickness of the back layer is in a range of preferably from 0.8 μm to 12 μm and particularly preferably from 1.0 μm to 10 μm.

When the thickness of the back layer is in the above range, a backsheet that includes therein the polymer sheet of the present invention may be provided with an improved durability (weather resistance) particularly as an outmost layer, and also provided with an excellent face condition and an improved adhesion.

Method of Forming Back Layer

The back layer may be formed by coating and drying a coating liquid that forms the back layer. After drying, the coating liquid may be cured by heating or the other treatment. There is not any particular limitation on the method of coating and the solvent of the coating liquid.

As the method of coating, for instance, a method of using a gravure coater or a bar coater may be used.

The solvent used for the coating liquid may be water or an organic solvent such as toluene, methylethyl ketone or the like. The solvent may be used each kind singularly or in a mixture of two or more kinds thereof. Note that, a method of coating a waterborne coating liquid that is prepared by dispersing a binder such as a fluorocarbon polymer in water is preferred. In this case, the ratio of water in the solvent is preferably 60% by mass or more and more preferably 80% by mass or more. When water shares 60% by mass or more of the solvent of the coating liquid that forms a fluorocarbon polymer layer, environmental burden may be minimized desirably.

Undercoat Layer

In the polymer sheet for the solar cell backsheet according to the present invention, an undercoat layer may be disposed between the specific polymer layer and the back layer, or between the support and the specific polymer layer. The thickness of the undercoat layer is in a range of preferably 2 μm or less, more preferably from 0.05 μm to 2 μm, and even more preferably from 0.1 μm to 1.5 μm. When the thickness is 2 μm or thinner, face condition may be maintained properly. When the thickness is 0.05 μm or thicker, necessary adhesiveness is easily secured.

The undercoat layer may include a binder therein. As the binder, for instance, polyester, polyurethane, acrylic resin, polyolefin, and the like may be used. In addition, to the undercoat layer, besides the binder, a cross-linking agent of epoxy-based, isocyanate-based, melamine-based, carbodiimide-based, oxazoline-based and the like, a surfactant such as anionic or nonionic, or filler such as silica may be added.

There is not any particular limitation on a method of applying the undercoat layer and on a solvent of the coating liquid that is used therein.

As a coating method, for example, a method using a gravure coater, a bar coater or the like may be used.

The solvent used for the coating liquid may be water or an organic solvent such as toluene, methylethyl ketone or the like. The solvent may be used in a manner of one kind alone or two or more kinds in a mixture.

Furthermore, application may be performed onto a polymer base material that has been biaxially stretched. In another method, application may be performed onto a polymer base material that has been uniaxially stretched, and then the polymer base material may be further stretched in a direction different from the uniaxial direction. In still another method, application may be performed onto a base material before being stretched, and then the base material may be stretched in two directions.

Light Reflectivity

In the polymer sheet for the solar cell backsheet according to the present invention, a reflectance of light having a wavelength of 550 nm at a surface side of the polymer sheet where the solar cell is disposed is preferably 80% or more, more preferably 82% or more. Note that, “light reflectivity” denotes a ratio of an amount of emission light to an amount of incident light, wherein the incident light is reflected and then emitted as the emission light.

When the light reflectivity is 80% or more, the light that passes through the cells and enters inside may be returned back to the cells effectively, whereby a large effect of increasing power generation efficiency is attained.

The light reflectance in the present invention is represented in terms of a reflectance of 550 nm light that is measured for a test sample with a spectrophotometer “UV-2450” (trade name, manufactured by Shimadzu Corp.) having an “ISR-2200” (trade name) integrating sphere attachment. Note that, as a reference, a light reflectance of a barium sulfate standard plate is measured and evaluated as 100%. Based on the reference, the light reflectance of a test sample is calculated.

Retention Percent of Elongation at Break

The polymer sheet of the present invention exhibits an elongation at break of preferably 50% or more, more preferably 60% or more, and even more preferably 70% or more after 50 hour storage under a condition of 120° C. and 100% RH, with respect to an elongation at break before storage. Note that, hereinafter, the retention percent of elongation at break of a backsheet after it is subjected to the wet and heat storage under the above condition with respect to an elongation at break before the treatment of the wet and heat storage is also referred to as “retention percent of elongation at break” simply.

Preparation of Polymer Sheet for Solar Cell Backsheet

The polymer sheet of the present invention may be prepared by any method as long as the method is capable of forming the specific polymer layers and, when needed, the other layers (readily-adhesive layer or the like) on the support as described above.

As an exemplary embodiment of forming the other layers, there may be mentioned (1) a method of forming the other layers by applying a coating liquid that contains constituents of the other layers onto a face of the polymer sheet. Examples of the method include the aforementioned methods of forming the readily-adhesive layer, undercoat layer, or back layer.

Specific examples of the polymer sheet of the present invention that is formed in accordance with the method described above may include: a sheet having a light reflection layer that contains a white pigment and is formed as the other layer by coating on one face of the polymer sheet of the present invention; a sheet having a color layer that contains a color pigment and is formed as the other layer by coating on one face of the polymer sheet of the present invention; and a sheet having a light reflection layer that contains a white pigment and an readily-adhesive layer, which are formed as the other layers on one face of the polymer sheet of the present invention.

Further, as another exemplary embodiment of forming the other layers, there may be mentioned (2) a method of laminating a sheet (film) having at least one layer that exerts functions expected as the other layer onto a face of the polymer sheet.

The sheet (film) that is used when the above method (2) is applied has at least one layer that exerts functions expected as the other layer. Exemplary embodiments of laminating the sheet onto the polymer sheet of the present invention may include: an embodiment of laminating a polymer film that contains a white pigment onto one face of the polymer sheet of the present invention; an embodiment of laminating a color film that contains a color pigment onto one face of the polymer sheet of the present invention; an embodiment of laminating an aluminum thin film and a polymer film that contains a white pigment onto one face of the polymer sheet of the present invention; and an embodiment of laminating a polymer film that has an inorganic barrier layer and another polymer film that contains a white pigment onto one face of the polymer film of the present invention.

Solar Cell Module

A solar cell module according to the present invention is configured as: solar cells that convert light energy of sun light into electrical energy are disposed between a transparent substrate through which sun light enters and the above described solar cell backsheet; and the solar cells are sealed and adhered with an ethylene-vinylacetate copolymer-based sealing material between the transparent substrate and the backsheet.

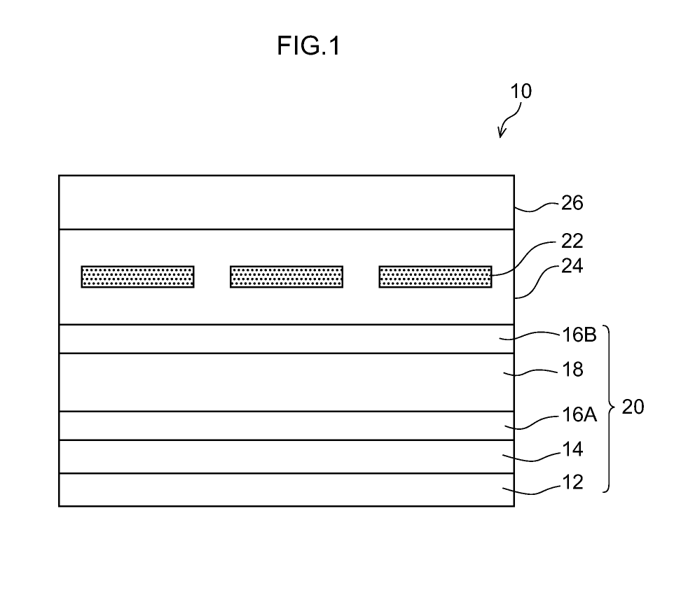

FIG. 1 shows schematically an example of a configuration of a solar cell module according to the present invention. The solar cell module 10 is configured as: solar cell elements 22 that convert solar light energy into electric energy are disposed between a transparent substrate 26 through which sun light enters and a solar cell backsheet 20 of the present invention; and a space formed between the substrate 26 and the backsheet 20 is sealed with an ethylene-vinylacetate copolymer-based sealant. The backsheet 20 is configured as: a specific polymer layer 16B is disposed on a face of a support 18 on the side of the solar cell elements 22; and on the other face thereof, a specific polymer layer 16A, an undercoat layer 14, and a back layer 12 are disposed in this order from the side of the support.

In another example of the configuration of the solar cell module according to the present invention, a readily-adhesive layer (not shown in the FIGURE) is further disposed between the specific polymer layer 16B and the sealant 24 in FIG. 1.

Regarding members other than the solar cell module, the solar cells, and the backsheet, they are described in detail in “Taiyoko Hatsuden System Kosei Zairyo” (under the supervision of Eiichi Sugimoto, published by Kogyo Chosakai Publishing, Inc., 2008), for example.

The transparent base board may only has a light transparency to such an extent that sunlight is allowed to pass through it, and may be selected appropriately from base materials that allow light to transmit therethrough. From the viewpoint of power generation efficiency, a transparent base board that has a higher light transmittance is more preferable. For such a transparent base board, a glass base board, a transparent resin such as acrylic resin and the like may be suitably used, for example.

For the solar cell elements, various kinds of known solar cell elements may be used, including: solar cells based on silicon such as single crystal silicon, polycrystalline silicon, or amorphous silicon; and solar cells based on a III-V or II-VI compound semiconductor such as copper-indium-gallium-selenium, copper-indium-selenium, cadmium-tellurium, or gallium-arsenic.

### EXAMPLES

The present invention will be further described in detail with reference to the following examples, but it should be construed that the present invention is in no way limited to those examples as long as not departing from the scope of the invention. Note that, if not otherwise specified particularly, “part(s)” and “%” are on the basis of mass.

Note that, volume average particle size was measured by using a laser diffraction particles size distribution analyzer “LA-950” (trade name, manufactured by HORIBA, Ltd.).

### Example 1

### Preparation of Support

—Synthesis of Polyester—

Slurry that included 100 kg of high purity terephthalic acid (manufactured by MITSUI CHEMICALS, INC.) and 45 kg of ethyleneglycol (manufactured by NIPPON SHOKUBAI CO., LTD.) was fed successively over 4 hours to an esterification tank that was kept at a temperature of 250° C. and a pressure of 1.2×10⁵ Pa and was preliminary loaded with 123 kg or about 123 kg of bis(hydroxyethyl) terephthalate. After feeding was completed, esterification was still continued for 1 hour. After that, 123 kg of resulting esterification product were transferred to a polycondensation reactor tank.

Then, ethyleneglycol in an amount of 0.3% by mass with respect to a polymer to be obtained was added to the polycondensation reactor tank where the esterification product had been transferred. After 5 minute agitation, an ethyleneglycol solution that contained cobalt acetate and another ethyleneglycol solution that contained manganese acetate were added in a manner that 30 ppm of cobalt acetate in term of the cobalt element, and 15 ppm of manganese acetate in term of the manganese element with respect to the polymer to be obtained were contained respectively in the resulting reaction mixture. After another 5 minute agitation, an ethyleneglycol solution that contained 2% by mass of a titanium alkoxide compound was added in a manner that the content thereof became 5 ppm in term of the titanium element with respect to the polymer to be obtained. Five minute later, an ethyleneglycol solution that contained 10% by mass of dimethyl phosphono ethylacetate was added in a manner that the content thereof became 5 ppm in term of the phosphorus element with respect to the polymer to be obtained. After that, the temperature of the reaction system was gradually elevated from 250° C. to 285° C. and the pressure was lowered to 40 Pa while the resulting polymer having a low molecular weight was agitated at 30 rpm. The time elapsed until the temperature reached a final temperature and the time elapsed until the pressure reached a final pressure, both times were selected to be 60 minutes. At the time when an agitation torque reached a predetermined value, the reaction system was purged with nitrogen gas, so that the pressure was restored to normal pressure and that polycondensation was terminated. Then, by ejecting into cold water in a strand form and immediate cutting out, polymer pellets (about 3 mm diameter and about 7 mm long) were obtained. Note that, the time elapsed from the start of reducing pressure to the time when the agitation torque reached the predetermined value was 3 hours.

Note that, as the above titanium alkoxide compound, a titanium alkoxide (Ti content: 4.44% by mass), which is synthesized in Example 1 described in the paragraph number [0083] of JP-A No. 2005-340616, was used.

Solid Phase Polymerization

Solid phase polymerization was carried out as: the above obtained pellets were left for 30 hours at 220° C. in a vacuum vessel that was maintained at a pressure of 40 Pa.

Preparation of Base

The pellets obtained after the solid-phase polymerization was fused at 280° C. and cast on a metal drum to form an about 3 mm thick non-stretched base. Then, the base was stretched at 90° C. in a longitudinal direction by 3 times, and further stretched at 120° C. in a transverse direction by 3.3 times. In this way, a 300 μm thick biaxially stretched polyethylene terephthalate support (hereinafter, referred to as “PET support”) was obtained.

Specific Polymer Layers 1 and 2

Preparation of White Inorganic Fine Particles Dispersion

Components included in the following composition were mixed and subjected to dispersing treatment for 1 hour with a dino-mill type dispersing machine.

Composition of White Inorganic Fine Particles Dispersion
Titanium dioxide (0.42 μm of volume average particle size) [“TIPAQUE R-780-2” (trade name), manufactured by ISHIHARA SANGYO KAISHA, LTD., 100% by mass of solid content]: 39.9% by mass,
Polyvinylalcohol [“PVA-105” (trade name), manufactured by KURARAY CO., LTD., 10% by mass of solid content]: 8.0% by mass,
Surfactant [“DEMOL EP” (trade name), manufactured by Kao Corp., 25% by mass of solid content]: 0.5% by mass, and
Distilled water: 51.6% by mass.

Preparation of Coating Liquid for Specific Polymer Layer

Components included in the following composition were mixed so as to prepare a coating liquid for a specific polymer layer.

Composition of Coating Liquid
White inorganic fine particles dispersion obtained above: 714.3 parts by mass,
Polyacrylic resin water dispersion [“JURYMER ET410” (trade name), manufactured by Nihon Junyaku Co., Ltd., binder P-1, 30% by mass of solid content]: 171.4 parts by mass,
Polyoxyalkylene alkylether [“NAROACTY CL95” (trade name), Sanyo Chemical Industries, Ltd., 1% by mass of solid content]: 26.8 parts by mass,
Oxazoline compound [“EPOCROS WS-700” (trade name), manufactured by Nippon Shokubai Co., Ltd., cross-linking agent A-1, 25% by mass of solid content]: 17.9 parts by mass, and
Distilled water: 69.6 parts by mass.

Preparation of Specific Polymer Layers 1 and 2

The resulting coating liquid for the specific polymer layer was applied onto the both surface of the PET support and dried at 180° C. for 1 minute, so that specific polymer layers 1 and 2 having a titanium dioxide content of 6.0 g/m² and a thickness of 2.6 μm were prepared.

In this way, a solar cell polymer sheet of Example 1 in which the specific polymer layers were formed on both faces of the PET support was prepared.

For the resulting polymer sheet, evaluations for retention percent of elongation at break, adhesion, adhesion after wet and heat storage (adhesion durability), light reflectance, and face condition were performed in accordance with the following methods.

Evaluation

1. Retention Percent of Elongation at Break

For the polymer sheets prepared as described above, retention percent (RP) (%) of elongation at break defined by the following equation was calculated from measured values of elongation at break, L0 and L1, which were obtained by the following method.

RP=L1/L0×100

In the above equation, the abbreviation “RP” denotes a retention percent of elongation at break.

Method of Measuring Elongation at Break

A polymer sheet is cut into a strip having a size of 10 mm width and 200 mm length, so that test specimens A and B for evaluation are prepared.

The test specimen A is subjected to humidity conditioning in an atmosphere of 25° C. and 60% RH for 24 hours, and then to a tensile test with “TENSILON” (trade name: manufactured by ORIENTEC Co., Ltd., RTC-1210A). The length of the test specimen to be stretched is 10 cm and the stretching speed is 20 mm/minute. Elongation at break of the test specimen A thus obtained is labeled as L0.

On the other hand, the test specimen B is subjected to wet and heat storage in an atmosphere of 120° C. and 100% RH for 50 hours, and then to the tensile test similarly to that for the test specimen A. Elongation at break of the test specimen B thus obtained is labeled as L1.

2. Adhesiveness

(A) Adhesiveness Before Lapse of Time Under Moisture and Heat

The polymer sheet produced as described above was cut to a size of 20 mm in width×150 mm, and thus two sheets of sample strips were prepared. These two sheets of sample strips were arranged such that the specific polymer layer side of each strip would face each other, and an EVA sheet (EVA sheet manufactured by Mitsui Chemicals Fabro, Inc.: SC50B, trade name) which had been previously cut to a size of 20 mm in width×100 mm in length was interposed between the two sheets. The two sheets of sample strips were adhered to the EVA by hot pressing the assembly using a vacuum laminator (vacuum laminating machine manufactured by Nisshinbo Holdings, Inc.). The conditions for adhesion at this time were as shown below.

The assembly was subjected to a vacuum at 128° C. for 3 minutes using a vacuum laminator, and thus provisional adhesion was achieved by pressing for 2 minutes. Thereafter, the assembly was subjected to a main adhesion treatment in a dry oven at 150° C. for 30 minutes. As such, there was obtained a sample for adhesion evaluation having an area of 20 mm from one edge of the two sheets of sample strips adhered to each other remaining unadhered to EVA, and having the remaining area of 100 mm adhered to the EVA sheet.

The EVA-unadhered area (an area of 20 mm wide from one edge of the sample strip) of the obtained sample for adhesion evaluation was clamped between upper and lower clips in a TENSILON (RTC-1210A, trade name, manufactured by Orientec Co., Ltd.), and a test was performed by drawing at a peeling angle of 180° and a rate of pulling of 300 mm/min. Thus the adhesive power was measured.

The adhesive power thus measured was used to grade the samples according to the following evaluation criteria. Among these, grades 4 and 5 fall in the practically acceptable range.

(Evaluation Criteria)

5: The adhesion was very good (60 N/20 mm or greater)

4: The adhesion was good (from 30 N/20 mm to less than 60 N/20 mm)

3: The adhesion was slightly poor (from 20 N/20 mm to less than 30 N/20 mm)

2: Adhesion failure occurred (from 10 N/20 mm to less than 20 N/20 mm)

1: Adhesion failure was noticeable (less than 10 N/20 mm)

(B) Adhesion After Wet and Heat Storage

A polymer sheet was stored under an atmospheric condition of 120° C. and 100% RH for 48 hours (wet and heat storage), and then adhesion was evaluated in a manner similar to the method describe in the section (A). The polymer sheet was rated in accordance with evaluation criteria similar to the criteria described in the section (A). Note that, an adhesion after the wet and heat storage that is ranked equal to or higher than “3” is in a practically allowable range. Ranks 4 and 5 are more preferable practically.

4. Light Reflectance

For the polymer sheets prepared as describe above, reflectance of 550 nm light was measured with a spectrophotometer “UV-2450” (trade name, manufactured by Shimadzu Corp.) having an “ISR-2200” (trade name) integrating sphere attachment. Note that, as a reference, a light reflectance of a barium sulfate standard plate was measured and evaluated as 100%. Based on this reference, the light reflectance of the polymer sheet was calculated.

5. Surface State

The surface state of the polymer sheet produced as described above was visually observed and evaluated according to the following evaluation criteria. Among these, grades 4 and 5 fall in the practically acceptable range.

### <Evaluation Criteria>

5: Unevenness or fisheyes were not at all observed.

4: Unevenness was very slightly observed, but fisheyes were not confirmed.

3: Unevenness was slightly observed, but fisheyes were not confirmed.

2: Unevenness was clearly confirmed, and fisheyes were observed in some areas (fewer than 10 fisheyes/m²).

1: Unevenness was clearly confirmed, and 10 or more fisheyes/m² were observed.

### Examples 2 to 10, Comparative Examples 1 to 4

Polymer sheets of Examples 2 to 10 and Comparative Examples 1 to 4 were prepared in a manner substantially similar to that in Example 1, except that the coating amounts of titanium dioxide and binder in the specific polymer layers 1 and 2 in Example 1 were changed as shown in Table 1. These polymer sheets were subjected to evaluation. The evaluation results are shown in Table 1.

### Comparative Examples 5 and 6

Polymer sheets of Comparative Examples 5 and 6 were prepared in a manner substantially similar to that in Example 1, except that the coating amounts of titanium dioxide and binder in the specific polymer layers 1 and 2 in Example 1 were changed as shown in Table 1 and that only the specific polymer layer was disposed on one face of the support, but the specific polymer layer 2 was not disposed. These polymer sheets were subjected to evaluation. The evaluation results are shown in Table 1.

### Examples 11 to 16

Polymer sheets of Examples 11 to 16 were prepared in a manner substantially similar to that in Example 1, except that the addition amount of crosslinking agent in the specific polymer layers 1 and 2 in Example 1 was changed as shown in Table 1. These polymer sheets were subjected to evaluation. The evaluation results are shown in Table 1.

### Examples 17 to 20

Polymer sheets of Examples 17 to 20 were prepared in a manner substantially similar to that in Example 1, except that the kinds and amounts of binder and crosslinking agent used in the specific polymer layers 1 and 2 in Example 1 were changed as shown in Table 1. These polymer sheets were subjected to evaluation. The evaluation results are shown in Table 1.

### Example 21

### Preparation of Support

A 300 μm thick biaxially stretched polyethylene terephthalate support (also referred to as “PET support”) was prepared in substantially the same manner as that in Example 1.

Specific Polymer Layer 1

—Preparation of White Inorganic Fine Particles Dispersion—

Components included in the following composition were mixed and subjected to dispersing treatment for 1 hour with a dino-mill type dispersing machine.

Composition of White Inorganic Fine Particles Dispersion
Titanium dioxide (0.42 μm of volume average particle size) [“TIPAQUE R-780-2” (trade name), manufactured by ISHIHARA SANGYO KAISHA, LTD., 100% by mass of solid content]: 50.3% by mass,
Aqueous solution of polyvinyl alcohol [“PVA-105” (trade name), manufactured by KURARAY CO., LTD., 10% by mass of solid content]: 2.5% by mass,
Surfactant [“DEMOL EP” (trade name), manufactured by Kao Corp., 25% by mass of solid content]: 0.2% by mass, and
Distilled water: 47.0% by mass.

Preparation of Coating Liquid for Specific Polymer Layer 1

Components included in the following composition were mixed so as to prepare a coating liquid for a specific polymer layer 1.

Composition of Coating Liquid
White inorganic fine particles dispersion obtained above: 456.6 parts by mass,
Water dispersion of acryl/silicone-based resin [“CERANATE WSA1070” (trade name: manufactured by DIC Corp.), binder P-3, 40% by mass of solid content]: 350.0 parts by mass,
Carbodiimide compound [CARBODILITE V-02-L2 (trade name, manufactured by Nisshinbo Industries, Inc.), crosslinking agent A-2, 40% by mass of solid content]: 24.5 parts by mass,
Oxazoline compound [“EPOCROS WS-700” (trade name), manufactured by Nippon Shokubai Co., Ltd., cross-linking agent A-1, 25% by mass of solid content]: 16.8 parts by mass,
Surfactant (“NAROACTY CL95” (trade name: manufactured by Sanyo Chemical Industries, Ltd., 1% by mass of solid content)): 15.0 parts by mass, and
Distilled water: 137.1 parts by mass.

—Preparation of Specific Polymer Layer 1—

The resulting coating liquid for the specific polymer layer was applied onto the one surface of the PET support and dried at 180° C. for 1 minute, so that specific polymer layer 1 having a binder of 4.0 g/m², a titanium dioxide of 10.8 g/m² and a thickness of 5.2 μm was prepared.

Protective Polymer Layer

Preparation of Coating Liquid for Protective Polymer Layer

Components included in the following composition were mixed so as to prepare a coating liquid for a protective polymer layer.

Composition of Coating Liquid for Protective Polymer Layer
Water dispersion of fluorocarbon-based resin [“OBBLIGATO SW0011F; (trade name, manufactured by AGC COAT-TECH Co., Ltd.), binder, 39% by mass of solid content]: 247.8 parts by mass,
Carbodiimide compound [CARBODILITE V-02-L2 (trade name, manufactured by Nisshinbo Industries, Inc.), crosslinking agent A-2, 40% by mass of solid content]: 24.2 parts by mass,
Surfactant (“NAROACTY CL95” (trade name: manufactured by Sanyo Chemical Industries, Ltd., 1% by mass of solid content)): 24.2 parts by mass, and
Distilled water: 703.8 parts by mass.

—Preparation of Protective Polymer Layer—

The resulting coating liquid for the protective polymer layer was applied onto the surface of the specific polymer layer 1 and dried at 180° C. for 1 minute, so that protective polymer layer having a binder of 2.0 g/m² and a thickness of 2.0 μm was prepared.

Specific Polymer Layer 2

Preparation of Coating Liquid for Specific Polymer Layer 2

Components included in the following composition were mixed so as to prepare a coating liquid for a specific polymer layer 2.

Composition of Coating Liquid
White inorganic fine particles dispersion obtained above: 411.4 parts by mass,
Water dispersion of polyolefin [“ARROWBASE SE-1013N” (trade name: manufactured by UNITIKA LTD.), binder P-4, 20% by mass of solid content]: 247.1 parts by mass,
Polyoxyalkylene alkyl ether (“NAROACTY CL95” (trade name: manufactured by Sanyo Chemical Industries, Ltd., 1% by mass of solid content)): 26.8 parts by mass
Oxazoline compound [“EPOCROS WS-700” (trade name), manufactured by Nippon Shokubai Co., Ltd., cross-linking agent A-1, 25% by mass of solid content]: 17.9 parts by mass, and
Distilled water: 296.8 parts by mass.

—Preparation of Specific Polymer Layer 2—

The resulting coating liquid for the specific polymer layer was applied onto the one surface of the PET support (an opposite side to the side disposed the specific polymer layer 1 and the protective polymer layer) and dried at 180° C. for 1 minute, so that specific polymer layer 2 having a titanium dioxide of 10.8 g/m² and a thickness of 5.4 μm was prepared.

Protective Polymer Layer

Polymer sheet for a solar cell of Example 21 in which the specific polymer layer 1 and the protective polymer layer were formed onto the one surface of the PET support, and the specific polymer layer 2 was formed onto the another surface of the PET support, was thus prepared. For the resulting polymer sheet, evaluations for retention percent of elongation at break, adhesion, adhesion after wet and heat storage (adhesion durability), light reflectance, and face condition were performed in a manner substantially the same as that in Example 1. The evaluation results are shown in Table 1.

### Example 22

### Preparation of Support

Polymer sheet for a solar cell of Example 22 was prepared in a manner substantially similar to that in Example 21 except that the coating liquid for the protective polymer layer in Example 21 was replaced with a coating liquid for a protective polymer layer having the following composition in Example 22, and was evaluated in a manner substantially the same as that in Example 21. The evaluation results are shown in Table 1.

Preparation of Coating Liquid for Protective Polymer Layer

Components included in the following composition were mixed so as to prepare a coating liquid for a protective polymer layer.

Composition of Coating Liquid for Protective Polymer Layer
Water dispersion of acryl/silicone-based resin [“CERANATE WSA1070” (trade name: manufactured by DIC Corp.), binder P-3, 40% by mass of solid content]: 247.8 parts by mass,
Carbodiimide compound [CARBODILITE V-02-L2 (trade name, manufactured by Nisshinbo Industries, Inc.), crosslinking agent A-2, 40% by mass of solid content]: 24.2 parts by mass,
Surfactant (“NAROACTY CL95” (trade name: manufactured by Sanyo Chemical Industries, Ltd., 1% by mass of solid content)): 24.2 parts by mass, and
Distilled water: 703.8 parts by mass.

TABLE 1

| | Specific Polymer Layer 1 | | | | | | | Specific Polymer Layer 2 | | | | | | Evaluation Result | | | | |
|---|---|---|---|---|---|---|---|---|---|---|---|---|---|---|---|---|---|---|
| | Binder | | TiO₂ | T/B | CLA | | | Binder | | TiO₂ | T/B | CLA | | RP | | | Refct. | |
| | Kind | [g/m²] | [g/m²] | Ratio | Kind | % | PL | Kind | [g/m²] | [g/m²] | Ratio | Kind | % | (%) | ABL | AAL | (%) | SS |
| Ex. 1 | P-1 | 2.1 | 6 | 2.86 | A-1 | 10 | N | P-1 | 2.1 | 6 | 2.86 | A-1 | 10 | 74 | 5 | 5 | 85 | 5 |
| C. Ex. 1 | P-1 | 2.1 | 2 | 0.95 | A-1 | 10 | N | P-1 | 2.1 | 2 | 0.95 | A-1 | 10 | 74 | 5 | 5 | 76 | 5 |
| Ex. 2 | P-1 | 2.1 | 4 | 1.90 | A-1 | 10 | N | P-1 | 2.1 | 4 | 1.90 | A-1 | 10 | 74 | 5 | 5 | 82 | 5 |
| Ex. 3 | P-1 | 2.1 | 10 | 4.76 | A-1 | 10 | N | P-1 | 2.1 | 10 | 4.76 | A-1 | 10 | 74 | 5 | 5 | 88 | 5 |
| Ex. 4 | P-1 | 2.1 | 12 | 5.71 | A-1 | 10 | N | P-1 | 2.1 | 12 | 5.71 | A-1 | 10 | 74 | 4 | 4 | 89 | 4 |
| C. Ex. 2 | P-1 | 2.1 | 16 | 7.62 | A-1 | 10 | N | P-1 | 2.1 | 16 | 7.62 | A-1 | 10 | 74 | 3 | 2 | 90 | 2 |
| C. Ex. 3 | P-1 | 0.7 | 6 | 8.57 | A-1 | 10 | N | P-1 | 0.7 | 6 | 8.57 | A-1 | 10 | 74 | 3 | 2 | 85 | 3 |
| Ex. 5 | P-1 | 0.8 | 6 | 7.50 | A-1 | 10 | N | P-1 | 0.8 | 6 | 7.50 | A-1 | 10 | 74 | 4 | 4 | 84 | 4 |
| Ex. 6 | P-1 | 1.0 | 6 | 6.00 | A-1 | 10 | N | P-1 | 1.0 | 6 | 6.00 | A-1 | 10 | 74 | 5 | 5 | 84 | 5 |
| Ex. 7 | P-1 | 1.2 | 6 | 5.00 | A-1 | 10 | N | P-1 | 1.2 | 6 | 6.00 | A-1 | 10 | 74 | 5 | 5 | 84 | 5 |
| Ex. 8 | P-1 | 1.5 | 6 | 4.00 | A-1 | 10 | N | P-1 | 1.5 | 6 | 4.00 | A-1 | 10 | 74 | 5 | 5 | 85 | 5 |
| Ex. 9 | P-1 | 3.5 | 6 | 1.71 | A-1 | 10 | N | P-1 | 3.5 | 6 | 1.71 | A-1 | 10 | 74 | 5 | 5 | 86 | 5 |
| Ex. 10 | P-1 | 4.0 | 6 | 1.50 | A-1 | 10 | N | P-1 | 4.0 | 6 | 1.50 | A-1 | 10 | 74 | 5 | 5 | 82 | 5 |
| C. Ex. 4 | P-1 | 4.5 | 6 | 1.33 | A-1 | 10 | N | P-1 | 4.5 | 6 | 1.33 | A-1 | 10 | 74 | 5 | 5 | 79 | 5 |
| C. Ex. 5 | P-1 | 1.2 | 6 | 5.00 | A-1 | 10 | N | N | — | — | — | N | — | 74 | 5 | 5 | 77 | 5 |
| C. Ex. 6 | P-1 | 4.2 | 24 | 5.71 | A-1 | 10 | N | N | — | — | — | N | — | 74 | 2 | 2 | 89 | 2 |
| Ex. 11 | P-1 | 2.1 | 6 | 2.86 | N | — | N | P-1 | 2.1 | 6 | 2.86 | N | — | 74 | 4 | 4 | 85 | 5 |
| Ex. 12 | P-1 | 2.1 | 6 | 2.86 | A-1 | 1 | N | P-1 | 2.1 | 6 | 2.86 | A-1 | 1 | 74 | 5 | 4 | 84 | 5 |
| Ex. 13 | P-1 | 2.1 | 6 | 2.86 | A-1 | 5 | N | P-1 | 2.1 | 6 | 2.86 | A-1 | 5 | 74 | 5 | 5 | 85 | 5 |
| Ex. 14 | P-1 | 2.1 | 6 | 2.86 | A-1 | 20 | N | P-1 | 2.1 | 6 | 2.86 | A-1 | 20 | 74 | 5 | 5 | 85 | 5 |
| Ex. 15 | P-1 | 2.1 | 6 | 2.86 | A-1 | 25 | N | P-1 | 2.1 | 6 | 2.86 | A-1 | 25 | 74 | 5 | 5 | 85 | 5 |
| Ex. 16 | P-1 | 2.1 | 6 | 2.86 | A-1 | 30 | N | P-1 | 2.1 | 6 | 2.86 | A-1 | 30 | 74 | 5 | 5 | 84 | 4 |
| Ex. 17 | P-2 | 1.2 | 6 | 5.00 | A-1 | 10 | N | P-1 | 2.1 | 6 | 2.86 | A-1 | 10 | 74 | 5 | 5 | 85 | 5 |
| Ex. 18 | P-3 | 1.2 | 6 | 5.00 | A-1 | 10 | N | P-1 | 2.1 | 6 | 2.86 | A-1 | 10 | 74 | 5 | 5 | 85 | 5 |
| Ex. 19 | P-11 | 1.2 | 6 | 5.00 | A-1 | 10 | N | P-1 | 2.1 | 6 | 2.86 | A-1 | 10 | 74 | 5 | 4 | 85 | 5 |
| Ex. 20 | P-1 | 1.2 | 6 | 2.86 | A-2 | 10 | N | P-1 | 2.1 | 6 | 2.86 | A-1 | 10 | 74 | 5 | 5 | 85 | 5 |
| Ex. 21 | P-3 | 4.0 | 10.8 | 2.70 | A-1/2 | 3/7 | Pr | P-4 | 4.0 | 10.8 | 2.70 | A-1 | 10 | 74 | 5 | 5 | 94 | 5 |
| Ex. 22 | P-3 | 4.0 | 10.8 | 2.70 | A-1/2 | 3/7 | Pr | P-4 | 4.0 | 10.8 | 2.70 | A-1 | 10 | 74 | 5 | 5 | 93 | 5 |

In Table 1, the abbreviation “Ex.” denotes “Example No.”, the abbreviation “C.Ex.” denotes “Comparative Example No.”, the abbreviation “T/B Ratio” denotes “a Ratio of the amount of TiO2 by weight per square meter to the amount of the binder by weight per square meter”, the abbreviation “CLA” denotes “Crosslinking Agent”, the abbreviation “PL” denotes “Protective polymer layer”, the abbreviation “RP” denotes “a retention percent of elongation at break”, the abbreviation “ABL” denotes “Adhesiveness before lapse of time under moisture and heat”, the abbreviation “AAL” denotes “Adhesiveness after lapse of time under moisture and heat”, “the abbreviation “Refct.” denotes “the light reflectance of the polymer sheet”, the abbreviation “SS” denotes “Surface state of the polymer sheet”, the abbreviation “N” denotes “none”, and the abbreviation “Pr” denotes “present”.

Note that, details of binders P-1, P-2, P-3 P-4 and P-11, and crosslinking agents A-1 and A-2 are as shown below.

Binder P-1: “JURYMER ET410” (trade name: manufactured by Nippon Junyaku K.K., polyacrylic resin),

Binder P-2: “CHEMIPEARL S75N” (trade name: manufactured by Mitsui Chemicals, Inc., polyolefin resin),

Binder P-3: “CERANATE WSA-1070” (trade names: manufactured by DIC Corp., silicone/acrylic resin, a content of polysiloxane structural moiety; about 30%),

Binder P-4: “ARROWBASE SE-1013N” (trade name: manufactured by UNITIKA LTD., polyolefin resin),

Binder P-11: “HYDRAN HW340” (trade name: manufactured by DIC Corp., urethane resin),

Crosslinking agent A-1: “EPOCROS WS-700” (trade name: manufactured by Nippon Shokubai Co., Ltd., oxazoline crosslinking agent), and

Crosslinking agent A-2: “CARBODILITE V-02-L2” (trade name: manufactured by Nisshinbo Industries, Inc., crosslinking agent).

As shown in Table 1, the polymer sheets obtained in Examples were superior in every property and performance of retention percent of elongation at break, adhesion, light reflectance, and face condition, as compared with Comparative Examples. These polymer sheets may be served as a solar cell backsheet.

### Example 23

On one face of a polymer sheet that was obtained in Example 1, a polymer layer A (undercoat layer) and a polymer layer B (back layer) were further formed, so that a solar cell backsheet of Example 23 was prepared.

Preparation of Polymer Layer A

Preparation of Coating Liquid for Polymer Layer A

Components included in the following composition were mixed, so that a coating liquid for the polymer layer A was prepared.

Composition of Coating Liquid
“CERANATE WSA-1070” (trade name: acryl/silicone binder, manufactured by DIC Corp., 40% by mass of solid content) (binder, P-3): 362.3 parts by mass,
Carbodiimide compound (“CARBODILITE V-02-L2” (trade name: manufactured by Nisshinbo Industries, Inc., 40% by mass of solid content)) (crosslinking agent, A-2): 48.3 parts by mass,
Surfactant (“NAROACTY CL95” (trade name: manufactured by Sanyo Chemical Industries, Ltd., 1% by mass of solid content)): 9.7 parts by mass, and
Distilled water: 543.5 parts by mass.

Preparation of Polymer Layer A

The resulting coating liquid for the polymer layer A was coated on one face (where the specific polymer layer 1 was formed) of a polymer sheet in a coating amount of 3.0 g/m² (in terms of the amount of binder) and dried at 180° C. for 1 minute, so that the polymer layer A (undercoat layer) with a dry thickness of about 3 μm was formed.

Preparation of Polymer Layer B

Preparation of Coating Liquid for Polymer Layer B

Ingredients described in the following prescription were mixed, so that a coating liquid for the polymer layer B was prepared.

Composition of Coating Liquid
“OBBLIGATO SSW0011F” (trade name: fluoro binder, manufactured by AGC COAT-TECH Co., Ltd., 39% by mass of solid content) (binder, P-101): 247.8 parts by mass,
Carbodiimide compound (“CARBODILITE V-02-L2” (trade name: manufactured by Nisshinbo Industries, Inc., 40% by mass of solid content)) (crosslinking agent, A-2): 24.2 parts by mass,
Surfactant (“NAROACTY CL95” (trade name: manufactured by Sanyo Chemical Industries, Ltd., 1% by mass of solid content)): 24.2 parts by mass, and
Distilled water: 703.8 parts by mass.

Preparation of Polymer Layer B

The resulting coating liquid for the polymer layer B was coated on the polymer layer A of a polymer sheet in a coating amount of 2.0 g/m² (in terms of the amount of binder) and dried at 180° C. for 1 minute, so that the polymer layer B (back layer) with a dry thickness of about 2 μm was formed.

In this way, a solar cell backsheet of Example 23 was formed.

### Example 24

On a face of the opposite side to the side formed of the back layer of the solar cell backsheet of Example 23, a readily-adhesive layer was further formed, so that a solar cell backsheet of Example 24 was prepared.

Preparation of Readily-Adhesive Layer

Preparation of Coating Liquid for Readily-Adhesive Layer

The components of the following composition were mixed, and a coating liquid for the readily-adhesive layer was prepared.

Composition of Coating Liquid

| | |
|---|---|
| Aqueous dispersion liquid of polyolefin resin | 5.2% by mass |
| (CHEMIPEARL S75N, trade name, manufactured by | |
| Mitsui Chemicals, Inc., solids content: 24% by | |
| mass: binder) | |
| Polyoxyalkylene alkyl ether | 7.8% by mass |
| (NAROACTY CL95, trade name, manufactured by | |
| Sanyo Chemical Industries, Ltd., solids content: | |
| 1% by mass) | |
| Oxazoline compound | 0.8% by mass |
| (EPOCROS WS-700, trade name, manufactured by | |
| Nippon Shokubai Co., Ltd., solids content: 25% | |
| by mass: crosslinking agent) | |
| Aqueous dispersion of silica fine particles | 2.9% by mass |
| (AEROSIL OX-50, trade name, manufactured by | |
| Nippon Aerosil Co., Ltd., volume average particle | |
| size = 0.15 μm, solids content: | |
| 10% by mass) | |
| Distilled water | 83.3% by mass |

Formation of Readily-Adhesive Layer

The coating liquid obtained was applied on the reflective layer so as to achieve an amount of binder of 0.09 g/m², and was dried for one minute at 180° C. Thus, a readily-adhesive layer was formed.

### Examples 25 to 28

A 3 mm thick tempered glass, an EVA sheet (“SC50B” (trade name), manufactured by Mitsui Chemicals Fabro, Inc.), crystalline solar cells, an EVA sheet (“SC50B” (trade name), manufactured by Mitsui Chemicals Fabro, Inc.), and each of the solar cell backsheets obtained in Examples 21 to 24 were respectively piled up together in this order and hot-pressed with a vacuum laminator (vacuum laminating machine, manufactured by Nisshinbo K.K), so that the backsheet and the EVA sheets were bonded together.

At this time, the backsheet was positioned in a manner that the face thereof where the specific polymer layer 2 was formed (the face where the protective polymer layer or the polymer layers A and B were not formed) was in contact with the EVA sheet. In addition, EVA bonding conditions are as follows.

With the vacuum laminator, after vacuum suction at 128° C. for 3 minutes, pressing was performed for 2 minutes for temporary boding. After that, full bonding was performed at 150° C. for 30 minutes in a dry oven.

In this way, solar cell modules of Examples 25 to 28 were respectively fabricated, which were crystalline solar cell modules that included therein each of the solar cell backsheets obtained in Examples 21 to 24.

Each of the solar cell modules fabricated in Examples 25 to 28 was subjected to power generation operation. Every solar cell module in Examples 25 to 28 exhibited power generation performance adequate as solar cells.

Further, delamination of the backsheet was not observed even after the solar cell modules of Examples 25 to 28 were left in an atmosphere of 120° C. and 100% RH for 48 hours. In addition, no color change was observed on the rear face of the solar cell modules. Good appearance was preserved.

According to the present invention, a polymer sheet for solar cell backsheets that has adequate adhesion and adhesion durability may be provided.

In addition, according to the present invention, a solar cell module that is low cost and has stable power generation efficiency may be provided.

The foregoing description of the exemplary embodiments of the present invention has been provided for the purposes of illustration and description. It is not intended to be exhaustive or to limit the invention to the precise forms disclosed. The embodiments were chosen and described in order to best explain the principles of the invention and its practical applications, thereby enabling others skilled in the art to understand the invention for various embodiments and with the various modifications as are suited to the particular use contemplated.

All publications, patent applications, and technical standards mentioned in this specification are herein incorporated by reference to the same extent as if such individual publication, patent application, or technical standard was specifically and individually indicated to be incorporated by reference. It will be obvious to those having skill in the art that many changes may be made in the above-described details of the preferred embodiments of the present invention. It is intended that the scope of the invention be defined by the following claims and their equivalents.

What is claimed is:

1. A polymer sheet for a solar cell backsheet, the polymer sheet comprising a support, and a polymer layer on each surface of the support, each polymer layer comprising white inorganic fine particles and a binder, a content of the white inorganic fine particles being in a range of from 4 g/m² to 12 g/m² per one polymer layer, and a content ratio (white inorganic fine particles/binder) of the white inorganic fine particles to the binder being in a range of from 1.5 to 8.0 by mass per one polymer layer.

2. The polymer sheet for a solar cell backsheet according to claim 1, wherein the binder is at least one polymer selected from the group consisting of a polyolefin resin, an acrylic resin and a silicone resin.

3. The polymer sheet for a solar cell backsheet according to claim 1, wherein one of the polymer layers comprises a silicone resin as the binder, and the other of the polymer layers comprises a polyolefin resin or an acrylic resin as the binder.

4. The polymer sheet for a solar cell backsheet according to claim 3, further comprising a protective polymer layer which comprises a resin selected from the group consisting of a silicone resin and a fluorocarbon resin, and inorganic fine particles in an amount of 1% by mass or less with respect to a total mass of the protective polymer layer, on the one of the polymer layers comprising the silicone resin as the binder.

5. The polymer sheet for a solar cell backsheet according to claim 1, wherein the polymer layer further comprises a crosslinking agent in a range of from 0.5% by mass to 25% by mass with respect to a total mass of the binder contained in the polymer layers.

6. The polymer sheet for a solar cell backsheet according to claim 1, wherein the support comprises polyester.

7. The polymer sheet for a solar cell backsheet according to claim 6, wherein the polyester is a straight chain saturated polyester that is synthesized from an aromatic dibasic acid or an ester-forming derivative thereof, and a diol or an ester-forming derivative thereof.

8. The polymer sheet for a solar cell backsheet according to claim 6, wherein the polyester is synthesized by solid phase polymerization by which a polymerization degree of the polyester is increased, after primary polymerization, by heating the polyester at a temperature in a range of from about 170° C. to about 240° C. for a period of about 5 to about 100 hours in a vacuum or in an atmosphere of nitrogen gas.

9. The polymer sheet for a solar cell backsheet according to claim 6, wherein a content of carboxyl groups in the polyester is 55 moles per ton or less.

10. The polymer sheet for a solar cell backsheet according to claim 1, wherein a thickness of the support is in a range of 25 μm to 300 μm.

11. The polymer sheet for a solar cell backsheet according to claim 1, wherein the white inorganic fine particles comprise at least one selected from the group consisting of titanium dioxide, barium sulfate, silicon oxide, aluminum oxide, magnesium oxide, calcium carbonate, kaolin, and talc.

12. The polymer sheet for a solar cell backsheet according to claim 1, wherein a volume average particle diameter of the white inorganic fine particles is in a range of from 0.15 μm to 0.50 μm.

13. The polymer sheet for a solar cell backsheet according to claim 4, wherein the crosslinking agent is a carbodiimide-based crosslinking agent or an oxazoline-based crosslinking agent.

14. The polymer sheet for a solar cell backsheet according to claim 1, further comprising a rear face protecting layer disposed on an opposite side of the support from a surface of the support that faces a cell side board.

15. The polymer sheet for a solar cell backsheet according to claim 14, wherein the rear face protecting layer comprises a fluorocarbon-based polymer or a silicone-based polymer, as a main binder.

16. The polymer sheet for a solar cell backsheet according to claim 1, wherein an elongation at break after storage for 50 hours under a condition of 120° C. and 100% RH, is 50% or more with respect to an elongation at break before the storage.

17. A solar cell module comprising the polymer sheet for a solar cell backsheet according to claim 1.
